(19) United States
(12) Patent Application Publication
(10) Pub. No.: US 2015/0261904 A1
(43) Pub. Date: Sep. 17, 2015

(54) PATTERN DATA GENERATION METHOD, PATTERN DATA GENERATION DEVICE, AND PATTERN DATA GENERATION PROGRAM

(71) Applicant: KABUSHIKI KAISHA TOSHIBA, Tokyo (JP)

(72) Inventors: Sachiko KOBAYASHI, Oota Tokyo (JP); Yoshihiro Naka, Yokohama Kanagawa (JP); Masafumi Asano, Yokohama Kanagawa (JP); Shoji Mimotogi, Yokohama Kanagawa (JP); Katsuyoshi Kodera, Yokohama Kanagawa (JP)

(73) Assignee: KABUSHIKI KAISHA TOSHIBA

(21) Appl. No.: 14/464,797

(22) Filed: Aug. 21, 2014

(30) Foreign Application Priority Data
Mar. 13, 2014 (JP) 2014-050762

(51) Int. Cl. G06F 17/50; H01L 21/033

(52) U.S. Cl. CPC G06F 17/5068; H01L 21/0337

(57) ABSTRACT

According to one embodiment, a pattern data generation method includes: decomposing data of a pattern to be formed into first guide pattern data and first DSA pattern data; generating a plurality of combinations of second guide pattern data and second DSA pattern data based on combinations of the first guide pattern data and the first DSA pattern data; carrying out simulation for each of the plurality of combinations of the second guide pattern data and the second DSA pattern data, and evaluating the simulation results using a predetermined evaluation function; and extracting one set or a plurality of sets of combinations that are suitable for forming the pattern to be formed, from among the plurality of combinations of the second guide pattern data and the second DSA pattern data, based on the evaluation results.

### CROSS-REFERENCE TO RELATED APPLICATIONS

This application is based upon and claims the benefit of priority from Japanese Patent Application No. 2014-050762, filed on Mar. 13, 2014; the entire contents of which are incorporated herein by reference.

### FIELD

Embodiments described herein relate generally to a pattern data generation method, pattern data generation device, and pattern data generation program.

### BACKGROUND

In recent years, the direct self assembly (DSA) process has been gaining attention for generation of microscopic patterns. In the DSA process, a guide pattern is formed on a substrate, and by forming a DSA pattern from a self assembly material with the guide pattern as a starting point, the required pattern is formed on the substrate.

In the DSA process, it is difficult to predict the shape of the pattern to be formed from the shape of the guide pattern alone, because the portion made from the self assembly material is interposed.

Therefore, in the DSA process, it is difficult to generate appropriate pattern data from the pattern design data alone.

### BRIEF DESCRIPTION OF THE DRAWINGS

FIG. 1 is a flowchart illustrating the pattern data generation method according to the first embodiment;

FIGS. 2A to 2D are schematic views illustrating the generation of second guide patterns 100-103;

FIGS. 3A to 3D are schematic views illustrating the generation of a plurality of combinations of the second guide pattern 100-103 data and the second DSA pattern 100a-103a data;

FIGS. 4A to 4C are schematic graphs showing evaluation using the evaluation function and extraction based on the evaluation results;

FIGS. 5A to 5D are schematic views illustrating the generation of a plurality of second guide patterns 110-113;

FIGS. 6A to 6D are schematic views illustrating setting of defects;

FIGS. 7A to 7D are schematic views illustrating evaluation in the case that the evaluation function is for the allowable defect size, and extraction; and

FIG. 8 is a schematic view illustrating the pattern data generation device 20 according to the second embodiment.

### DETAILED DESCRIPTION

In general, according to one embodiment, a pattern data generation method includes: decomposing data of a pattern to be formed into first guide pattern data and first DSA pattern data; generating a plurality of combinations of second guide pattern data and second DSA pattern data based on combinations of the first guide pattern data and the first DSA pattern data; carrying out simulation for each of the plurality of combinations of the second guide pattern data and the second DSA pattern data, and evaluating the simulation results using a predetermined evaluation function; and extracting one set or a plurality of sets of combinations that are suitable for forming the pattern to be formed, from among the plurality of combinations of the second guide pattern data and the second DSA pattern data, based on the evaluation results.

Embodiments will now be described with reference to the drawings. Note that the same numerals are applied to similar constituent elements in the drawings and detailed descriptions of such constituent elements are appropriately omitted.

### First Embodiment

First, a pattern data generation method according to the first embodiment is described.

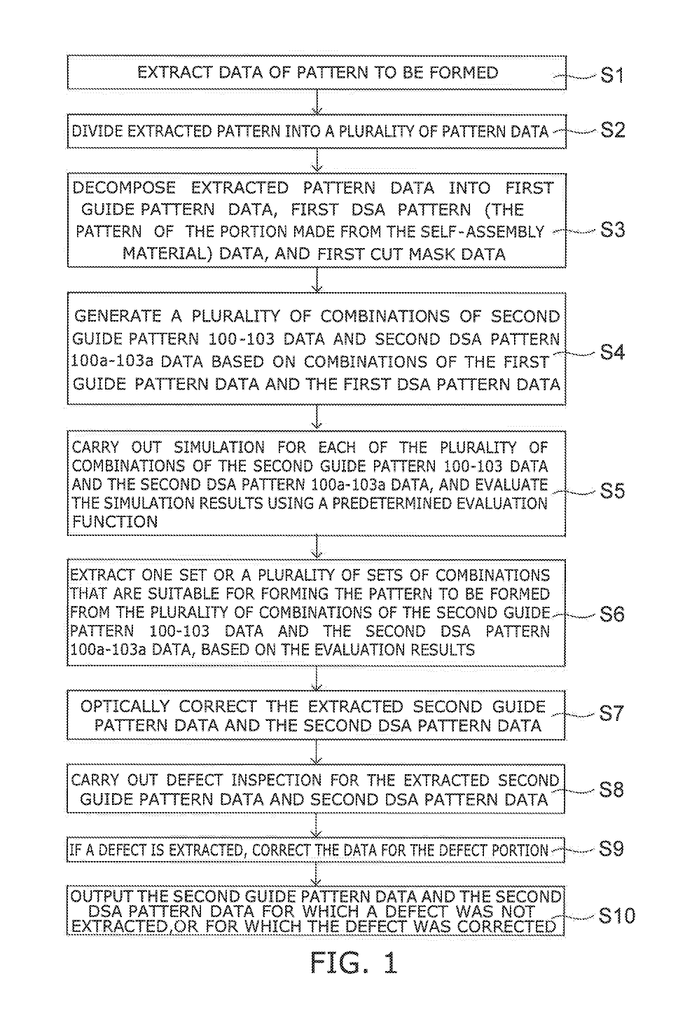

FIG. 1 is a flowchart illustrating the pattern data generation method according to the first embodiment.

As illustrated in FIG. 1, first, data for the pattern to be formed is extracted (step S1). The extracted data includes design data on the pattern to be formed or the like.

The target pattern can be, for example, a wiring pattern, a gate pattern, a dummy pattern, a pattern used for a three-dimensional transistor (FinFET), and the like. However, the target pattern is not limited to these examples, but may be any pattern that can be formed using the DSA process.

Next, the extracted pattern data is divided into a plurality of pattern data (step S2).

The extracted pattern data is divided into a plurality of pattern data, in order to simplify formation of the pattern in a light exposure device or the like. For example, data for the pattern layout to be formed is divided, to generate a plurality of divided layout data.

Depending on the shape of the pattern and the like, the extracted pattern data can be used as it is without dividing into a plurality of pattern data.

Next, the extracted pattern data is decomposed into first guide pattern data, first DSA pattern (the pattern of the portion made from the self-assembly material) data, and first cut mask data (step S3).

The cut mask is used to regulate the length and the like of the DSA pattern when the form of the DSA pattern is line and space or the like.

Therefore, first cut mask data may be decomposed from the extracted pattern data, if necessary.

The first DSA pattern data and the first cut mask data can be obtained from the data of the pattern to be formed and the first guide pattern data. For example, the form of the pattern to be formed (for example, shape and dimensions) is known, so if the form of the first guide pattern is determined, it is possible to determine the form of the first DSA pattern and the first cut mask.

For example, by determining the data associated with the form of the first guide pattern, the data associated with the form of the first DSA pattern is determined from the data associated with the form of the pattern to be formed and the data associated with the form of the first guide pattern.

Also, if the extracted pattern data is divided into a plurality of pattern data, the extracted pattern data is decomposed into first guide pattern data, first DSA pattern data, and first cut mask data for each of the plurality of divided pattern data.

Next, a plurality of combinations of second guide pattern 100-103 data and second DSA pattern 100a-103a data is generated based on combinations of the first guide pattern data and the first DSA pattern data (step S4).

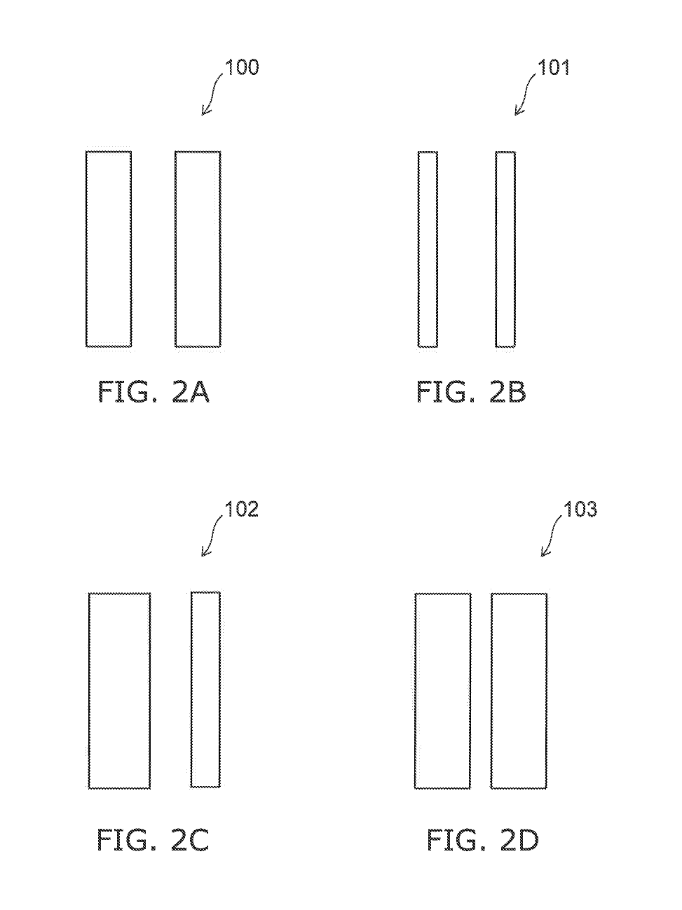

FIGS. 2A to 2D are schematic views illustrating the generation of second guide patterns 100-103.

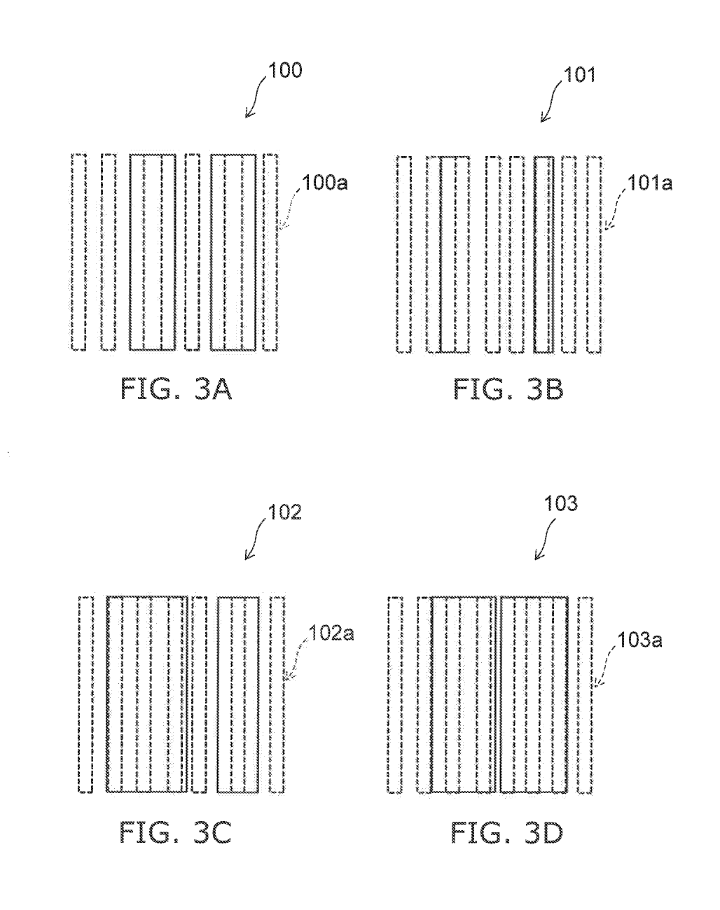

FIGS. 3A to 3D are schematic views illustrating the generation of a plurality of combinations of the second guide pattern 100-103 data and the second DSA pattern 100a-103a data.

For example, as illustrated in FIG. 2A to 2D, the plurality of second guide patterns 100-103 is generated by changing the dimensions of the first guide pattern as original.

The example illustrated in FIGS. 2A to 2D is a case in which the dimensions of a line and space first guide pattern is changed to generate the plurality of second guide pattern 100-103 data.

In this case, as illustrated in FIGS. 3A to 3D, the second DSA patterns 100a-103a and the second cut mask are determined corresponding to each of the second guide patterns 100-103.

For example, the data associated with the form of the second DSA patterns 100a-103a is determined from the data associated with the form of the pattern to be formed and the data associated with the form of the second guide patterns 100-103.

The form and number and the like of the second guide patterns 100-103 generated are not limited to those illustrated, but can be changed as appropriate in accordance with the form of the first guide pattern and the like.

Next, simulation is carried out for each of the plurality of combinations of the second guide pattern 100-103 data and the second DSA pattern 100a-103a data, and the simulation results are evaluated using a predetermined evaluation function (step S5).

Simulation and evaluation using a predetermined evaluation function can also be carried out for the second cut mask.

In this case, simulation of the second guide patterns 100-103 is carried out, then, simulation of the second DSA patterns 100a-103a can be carried out.

Simulation of the second guide patterns 100-103 and simulation of the second DSA patterns 100a-103a can be lithography simulations carried out for evaluation of lithography methods such as an optical lithography method, extreme ultraviolet lithography (EUV) method, nano imprint lithography method, and the like.

The simulation of the second guide patterns 100-103 and the simulation of the second DSA patterns 100a-103a can be carried out under a plurality of conditions taking into consideration the variation in dimensions (dimensional tolerances) caused by variations in the manufacturing process conditions.

The form of the second guide patterns 100-103 (for example, line and space, hole, and the like), material, dimensions, and the like can be taken into consideration in the simulation of the second guide patterns 100-103.

DSA information can be taken into consideration in the simulation of the second DSA patterns 100a-103a.

DSA information can include conditions that affect the size of the second DSA patterns 100a-103a, for example, DSA material (self assembly material), composition ratios, molecular weights, dimensions of the second DSA patterns 100a-103a, process conditions, and the like.

The evaluation function used for evaluating the simulation results can be, for example, a function that relates to the dimensional changes of the second DSA patterns 100a-103a to dimensional changes of the second guide patterns 100-103, a function related to changes in the free energy of the second DSA patterns 100a-103a associated with process variations, a function related to the convergence behavior of the free energy of the second DSA patterns 100a-103a, or, a function related to the dimensional variation of the second guide patterns 100-103 and the second DSA patterns 100a-103a with respect to the defect size, and the like.

The free energy of the second DSA pattern can be obtained when carrying out the simulation of the second DSA pattern.

Next, one set or a plurality of sets of combinations are extracted from the plurality of combinations of the second guide pattern 100-103 data and the second DSA pattern 100a-103a data that are suitable for forming the pattern to be formed, based on the evaluation results (step S6).

If necessary, the second cut mask is extracted corresponding to the extracted second DSA pattern.

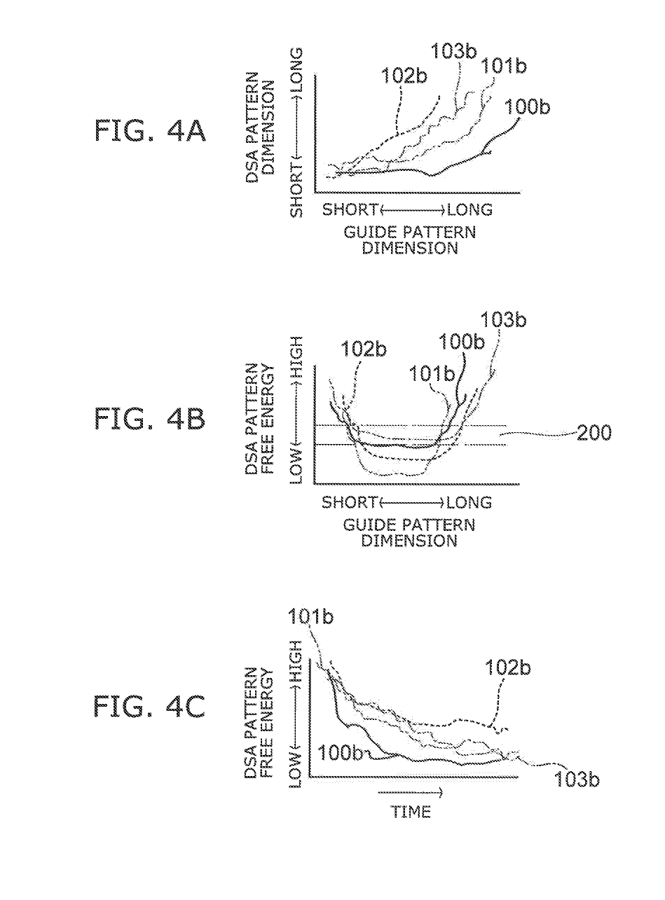

FIGS. 4A to 4C are schematic graphs showing evaluation using the evaluation function and extraction based on the evaluation results.

In the graphs, “100b” is the combination of the second guide pattern 100 and the corresponding second DSA pattern 100a. “101b” is the combination of the second guide pattern 101 and the corresponding second DSA pattern 101a. “102b” is the combination of the second guide pattern 102 and the corresponding second DSA pattern 102a, “103b” is the combination of the second guide pattern 103 and the corresponding second DSA pattern 103a.

FIG. 4A is a schematic graph showing evaluation for the case where the evaluation function is dimensional variation in the second DSA patterns 100a-103a with respect to the dimensional variation in the second guide patterns 100-103, and extraction.

If dimensional variation of the second DSA patterns 100a-103a with respect to the dimensional variation in the second guide patterns 100-103 is little, it is possible to reduce the dimensional variation of the pattern to be formed, and therefore to improve the yield and quality.

Therefore, of the results shown in FIG. 4A, “100b” can be evaluated as the most suitable, so “100b” is extracted.

FIG. 4B is a schematic graph showing evaluation for the case where the evaluation function is the variation of free energy of the second DSA patterns 100a-103a associated with process variations, and extraction.

The process generating the second DSA patterns 100a-103a is affected by the free energy of the second DSA patterns 100a-103a.

As a result of process variations, dimensional changes are produced in the second guide patterns 100-103, and if the free energy of the second DSA patterns 100a-103a changes in accordance with these changes, dimensional changes in the second DSA patterns 100a-103a are produced in accordance with the change in free energy.

Therefore, even if dimensional changes are produced in the second guide patterns 100-103 as a result of process variations, provided the free energy of the second DSA patterns 100a-103a is within a predetermined range 200, the process of generating the second DSA patterns 100a-103a is stabilized, so it is possible to stabilize the dimensions of the second DSA patterns 100a-103a.

For example, of the results shown in FIG. 4B, “100b” and “101b” can be evaluated as suitable, so “100b” and “101b” are extracted.

FIG. 4C is a schematic graph showing evaluation for the case where the evaluation function is the convergence behavior of the free energy of the second DSA patterns 100a-103a, and extraction.

As described previously, the process generating the second DSA patterns 100a-103a is affected by the free energy of the second DSA patterns 100a-103a.

Therefore, if the free energy of the second DSA patterns 100a-103a converge in a short period of time and to a low value, the process of generating the second DSA patterns 100a-103a is stabilized, so it is possible to stabilize the dimensions of the second DSA patterns 100a-103a.

For example, of the results shown in FIG. 4C, “100b” can be evaluated as most suitable, so “100b” is extracted.

Next, an example is described in which the evaluation function is the dimensional variation in the second guide patterns 100-103 and the second DSA patterns 100a-103a with respect to defect size.

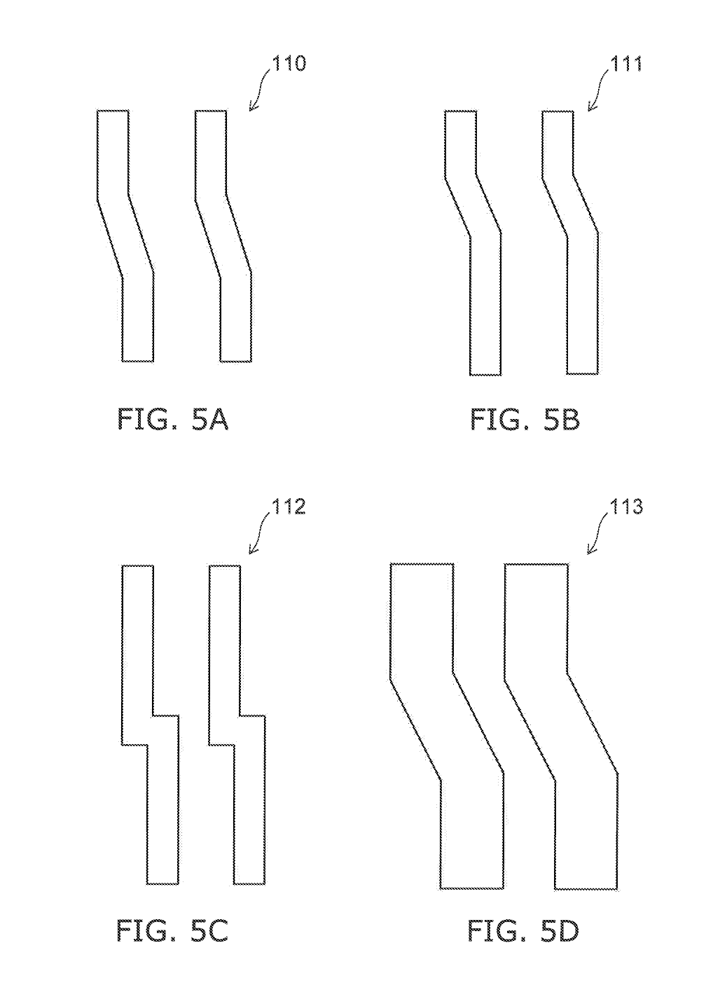

FIGS. 5A to 5D are schematic views illustrating the generation of a plurality of second guide patterns 110-113.

FIGS. 2A to 2D are cases in which a plurality of linear line and space second guide patterns 100-103 is generated, but FIGS. 5A to 5D are cases in which a plurality of line and space second guide patterns 110-113 having a bend portion is generated.

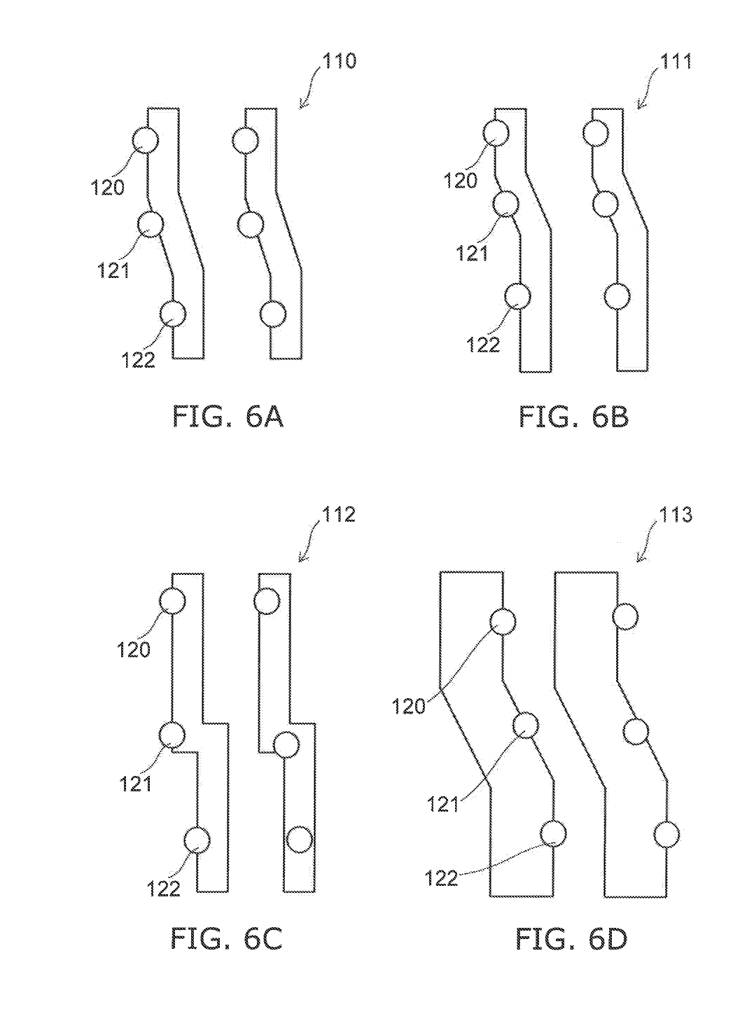

FIGS. 6A to 6D are schematic views illustrating setting of defects.

First, as illustrated in FIGS. 5A to 5D, a plurality of second guide patterns 110-113 is generated by varying the dimensions of the first guide pattern.

In this case, the second DSA pattern and the second guide mask are determined corresponding to each of the second guide patterns 110-113.

The form and number and the like of the second guide patterns 110-113 generated are not limited to those illustrated, but can be changed as appropriate in accordance with the form of the first guide pattern and the like.

Next, as illustrated in FIGS. 6A to 6D, defects 120-122 are set near to the second guide patterns 110-113. The defects 120-122 are assumed to have the same size and shape.

The defects 120-122 can be, for example, white defects, black defects, open defects, short defects, and the like.

The type, size, arrangement, number, shape, and the like of the defects 120-122 may be varied.

Next, a predetermined simulation is carried out for each of the combination of second guide patterns 110-113 and second DSA patterns, in the same way as described previously. Then, by evaluating the simulation results using a predetermined evaluation function, the second guide pattern and the corresponding second DSA pattern suitable for generation of the pattern to be formed are extracted. Also, if necessary, the second cut mask is extracted corresponding to the extracted second DSA pattern.

In the case of an evaluation function for the dimensional variation with respect to defect size, for example, the evaluation function can be at least for an allowable defect size, and a region in which the occurrence of a defect is allowed.

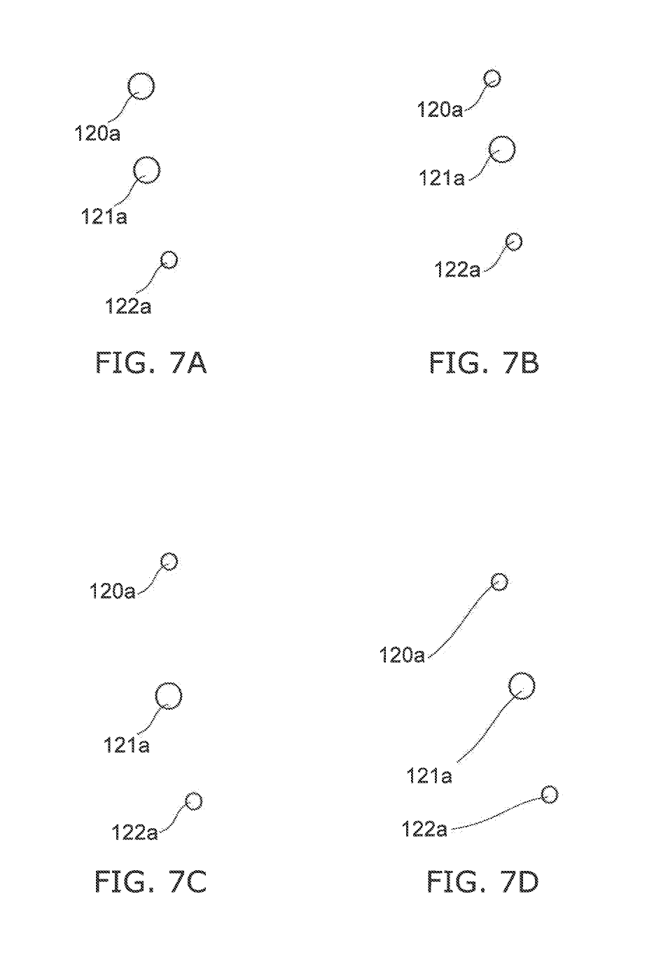

FIGS. 7A to 7D are schematic views illustrating evaluation in the case that the evaluation function is for the allowable defect size, and extraction.

The allowable defects 120a-122a in FIGS. 7A to 7D correspond to the defects 120-122 in FIGS. 6A to 6D, respectively.

The size of the allowable defects 120a-122a represents the allowable defect size.

In other words, the larger the size of the allowable defects 120a-122a, the smaller the dimensional variation with respect to defect size. In other words, the resistance to the occurrence of defects is high. For example, of the cases illustrated in FIGS. 7A to 7D, the case in FIG. 7A, namely, the combination of the second guide pattern 110 and the corresponding second DSA pattern, can be evaluated as most suitable. Therefore, the combination of the second guide pattern 110 and the corresponding second DSA pattern is extracted.

The combination of evaluation functions and pattern forms is not limited to those illustrated.

For example, an evaluation function that relates to dimensional variations and defect size can be applied to other pattern forms such as linear line and space, and the like.

Also, an evaluation function that relates to the dimensional changes of the second DSA pattern to dimensional changes of the second guide pattern, an evaluation function related to the change in the free energy of the second DSA pattern associated with process variations, and an evaluation function related to the convergence behavior of the free energy of the second DSA pattern can be applied to other pattern forms such as line and space having a bend portion, and the like.

Also, the evaluation function can be applied to pattern forms other than the pattern forms illustrated (for example, holes, and the like).

Also, the evaluation function can be selected as appropriate in accordance with the pattern form.

The extraction as described above can be carried out based on the evaluation results for a single evaluation function, or it can be carried out comprehensively taking into consideration the evaluation results for each of a plurality of evaluation functions.

In the extraction using evaluation functions, when a plurality of sets of combination of suitable second guide patterns and second DSA patterns is extracted (for example, in the case illustrated in FIG. 4B), the results can be further narrowed down taking into consideration the evaluation results of other evaluation functions, productivity, test results, and the like.

For example, it is possible to extract the combination of second guide pattern and second DSA pattern that is most appropriate comprehensively taking into consideration each of the evaluation results illustrated in FIGS. 4A to 4C or FIGS. 7A to 7C.

Next, as illustrated in FIG. 1, optical correction is carried out for the extracted second guide pattern data and the second DSA pattern data (step S7).

Optical correction can also be carried out for the second cut mask data.

The optical correction can be, for example, an optical proximity correction or resolution enhanced technology process, and the like.

Next, defect inspection is carried out for the extracted second guide pattern data and the second DSA pattern data (step S8).

Defect inspection can also be carried out for the second cut mask data.

The defect inspection can be carried out by, for example, a lithography compliance checking (LCC) process or the like.

Next, if a defect is extracted, the data for the defect portion is corrected (step S9).

Next, the second guide pattern data and the second DSA pattern data from which a defect was not extracted, or for which the defect was corrected, is output (step S10).

Also, if necessary, the second cut mask data for which a defect was not extracted or for which the defect was corrected is output.

According to the pattern generation method of this embodiment, it is possible to generate suitable pattern data.

### Second Embodiment

Next, a pattern data generation device 20 according to the second embodiment is described.

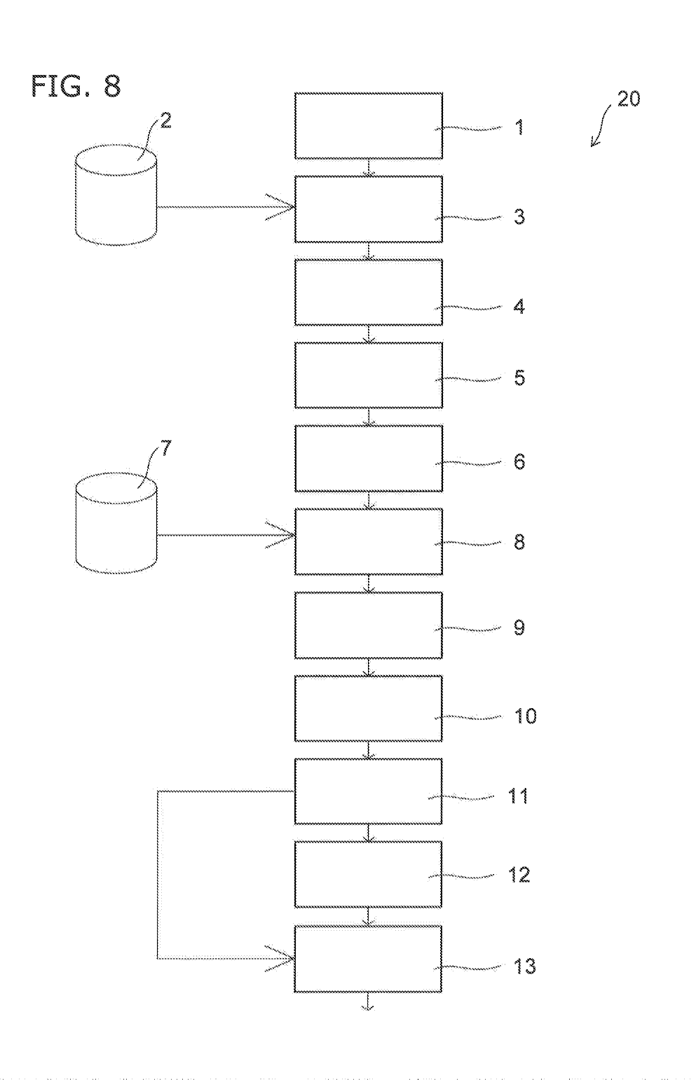

FIG. 8 is a schematic view illustrating the pattern data generation device 20 according to the second embodiment.

The pattern data generation device 20 can execute the pattern data generation method as described previously.

As illustrated in FIG. 8, the pattern data generation device 20 includes an input unit 1, a pattern data storage unit 2, a data extraction unit 3, a pattern division unit 4, a pattern decomposition unit 5, an evaluation pattern generation unit 6, an evaluation data storage unit 7, an evaluation unit 8, a pattern extraction unit 9, a correction unit 10, a defect detection unit 11, a defect correction unit 12, and an output unit 13.

The input unit 1 inputs data for defining the pattern to be formed into the data extraction unit 3. The input unit 1 can be, for example, a keyboard, a bar code reader, or the like.

The pattern data storage unit 2 stores the data for the pattern to be formed. The pattern data storage unit 2 stores, for example, pattern design data and the like.

The target pattern can be, for example, a wiring pattern, a gate pattern, a dummy pattern, a pattern used for a three-dimensional transistor (FinFET), and the like.

However, the target pattern is not limited to these examples, but may be any pattern that can be formed using the DSA process.

The data extraction unit 3 extracts the applicable pattern data from the pattern data stored in the pattern data storage unit 2, based on the data input from the input unit 1.

The extracted pattern data is input to the pattern division unit 4.

The pattern division unit 4 divides the pattern data input from the data extraction unit 3 into a plurality of pattern data.

The divided pattern data is input to the pattern decomposition unit 5.

Depending on the shape of the pattern and the like, the extracted pattern data can be input to the pattern decomposition unit 5 as it is, without dividing into a plurality of pattern data.

The pattern decomposition unit 5 decomposes the pattern data input from the pattern division unit 4 into first guide pattern data, first DSA pattern data and first cut mask data.

The cut mask is used to regulate the length and the like of the DSA pattern when the form of the DSA pattern is line and space or the like.

Therefore, the first cut mask data may be divided if necessary.

The first guide pattern data, the first DSA pattern data, and the first cut mask data are input to the evaluation pattern generation unit 6.

The evaluation pattern generation unit 6 generates a plurality of combinations of the second guide pattern data and the second DSA pattern data, based on combinations of the first guide pattern data and the first DSA pattern data.

For example, data regarding the dimensions of the input first guide pattern is varied, and a plurality of second guide pattern data is generated.

Also, the second DSA pattern data and the second cut mask data are generated corresponding to each of the plurality of second guide pattern data.

The generated data is input to the evaluation unit 8.

The evaluation data storage unit 7 stores data regarding evaluation functions.

The evaluation functions can be the same as those described above, so their detailed description is omitted.

The evaluation unit 8 carries out simulation for each of the plurality of combinations of the second guide pattern data and the second DSA pattern data, and evaluates the simulation results using an evaluation function stored in the evaluation data storage unit 7.

At this time, the second cut mask data can also be evaluated.

The evaluation result data is input to the pattern extraction unit 9.

The pattern extraction unit 9 extracts one set or a plurality of sets of combinations suitable for forming the pattern to be formed, from among the plurality of combinations of the second guide pattern data and the second DSA pattern data, based on the evaluation results.

At this time, the second cut mask data can also be extracted.

The extraction can be carried out in the same way as described above, so its detailed description is omitted. The extracted second guide pattern data and second DSA pattern data are input to the correction unit 10. The extracted second cut mask data is also input to the correction unit 10.

The correction unit 10 performs optical correction on the second guide pattern data and the second DSA pattern data input from the pattern extraction unit 9.

If necessary, the correction unit 10 carries out optical correction on the second cut mask data input from the pattern extraction unit 9.

The optical correction is, for example, an optical proximity correction, a resolution enhanced technology process, or the like.

The second guide pattern data and the second DSA pattern data that have been optically corrected is input to the defect detection unit 11. The second cut mask data that has been optically corrected is also input to the defect detection unit 11.

The defect detection unit 11 detects defects in the second guide pattern data and the second DSA pattern data input from the correction unit 10.

If necessary, the defect detection unit 11 detects defects in the second cut mask data input from the correction unit 10.

Defect detection can be carried out by, for example, an LCC process or the like.

The extracted defect data (for example, data on the position or size of a defect) is input to the defect correction unit 12.

Second guide pattern data, second DSA pattern data, and second cut mask data for which defects were not extracted are input to the output unit 13.

The defect correction unit 12 corrects the defective portion of the data based on the defect data input from the defect detection unit 11.

The second guide pattern data, the second DSA pattern data, and the second cut mask data for which the data of the defective portion was corrected is input to the output unit 13.

The output unit 13 displays, stores, or outputs to an external device (for example, a database, a manufacturing device such as a light exposure device, and the like) the data input from the defect detection unit 11 or the defect correction unit 12.

According to the pattern data generation device 20 of this embodiment, it is possible to generate suitable pattern data.

### Third Embodiment

Next, a pattern data generation program according to the third embodiment is described.

The pattern data generation program according to this embodiment executes the pattern data generation method described above on a computer.

In order to execute the pattern data generation, the pattern data generation program is stored in, for example, a storage unit provided in the computer. The pattern data generation program is, for example, supplied to the computer in the form of storage on a recording medium, and stored in the storage unit provided in the computer by reading from the recording medium. The pattern data generation program can also be stored in the storage unit provided in the computer via a local area network (LAN) of a manufacturing execution system (MES).

The pattern data generation program that executes the following procedures (1) to (10) is stored in the storage unit provided in the computer.

(1) Procedure of extracting the pattern data to be formed.

(2) Procedure of dividing the extracted pattern data into a plurality of pattern data.

(3) Procedure of decomposing the extracted pattern data into first guide pattern data, first DSA pattern data, and first cut mask data.

(4) Procedure of generating a plurality of combinations of the second guide pattern data and the second DSA pattern data, based on combinations of the first guide pattern data and the first DSA pattern data.

Also, if necessary, a procedure of generating the second cut mask data.

(5) Procedure of carrying out simulation for each of the plurality of combinations of the second guide pattern data and the second DSA pattern data, and evaluating the simulation results using predetermined evaluation functions.

Also, if necessary, a procedure of carrying out simulation on the second cut mask data, and evaluating using predetermined evaluation functions.

(6) Procedure of extracting one set or a plurality of sets of combinations suitable for forming the pattern to be formed, from among the plurality of combinations of the second guide pattern data and the second DSA pattern data, based on the evaluation results.

Also, if necessary, a procedure of extracting the second cut mask data.

(7) Procedure of performing an optical correction on the extracted second guide pattern data and the second DSA pattern data.

Also, if necessary, a procedure of performing an optical correction on the second cut mask data.

(8) Procedure of detecting defects in the extracted second guide pattern data and second DSA pattern data.

Also, if necessary, a procedure of detecting defects in the second cut mask data.

(9) Procedure of correcting the defective portion of the data in the event that a defect is extracted.

(10) Procedure of outputting the second guide pattern data and the second DSA pattern data for which a defect has not been extracted or for which the defect has been corrected.

Also, if necessary, a procedure of outputting the second cut mask data for which a defect has not been extracted or for which the defect has been corrected.

The details of the above procedures can be the same as those described above, so their detailed description is omitted.

Also, the above procedures may be executed in a time series in accordance with the above sequence, or they may be executed in parallel or individually.

The pattern data generation program according to this embodiment may be processed by a single calculation means, or it may be processed in a dispersed manner by a plurality of calculation means.

By executing the pattern data generation program according to this embodiment, the pattern data generation method as described above is executed.

According to the pattern data generation program of this embodiment, it is possible to generate suitable pattern data.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Moreover, above-mentioned embodiments can be combined mutually and can be carried out.

What is claimed is:

1. A pattern data generation method, comprising: decomposing data of a pattern to be formed into first guide pattern data and first DSA pattern data;
generating a plurality of combinations of second guide pattern data and second DSA pattern data based on combinations of the first guide pattern data and the first DSA pattern data;
carrying out simulation for each of the plurality of combinations of the second guide pattern data and the second DSA pattern data, and evaluating the simulation results using a predetermined evaluation function; and
extracting one set or a plurality of sets of combinations that are suitable for forming the pattern to be formed, from among the plurality of combinations of the second guide pattern data and the second DSA pattern data, based on the evaluation results.

2. The method according to claim 1, wherein the evaluation function is at least one selected from the group consisting of a function related to the dimensional changes of the second DSA pattern with respect to the dimensional changes of the second guide pattern, a function related to the change in free energy of the second DSA pattern associated with process variations, a function related to the convergence behavior of the free energy of the second DSA pattern, and, a function related to the dimensional changes of the second guide pattern and the second DSA pattern with respect to defect size.

3. The method according to claim 1, wherein in the decomposing into the first guide pattern data and the first DSA pattern data,
data concerning the form of the first guide pattern is determined, and data concerning the form of the first DSA pattern is determined from data concerning the form of the pattern to be formed and data concerning the form of the first guide pattern.

4. The method according to claim 1, wherein in the decomposing into the first guide pattern data and the first DSA pattern data,
the data of the pattern to be formed is divided into a plurality of pattern data, and each of the plurality of divided pattern data is decomposed into first guide pattern data and first DSA pattern data.

5. The method according to claim 1, wherein in the generating a plurality of combinations of the second guide pattern data and the second DSA pattern data,
the dimensions of the first guide pattern are varied, and a plurality of second guide pattern data is generated.

6. The method according to claim 5, wherein in the generating a plurality of combinations of the second guide pattern data and the second DSA pattern data,
the data regarding the form of the second DSA pattern is determined from the data regarding the form of the pattern to be formed and the data regarding the form of the second guide pattern.

7. The method according to claim 1, wherein when carrying out the simulation for each of the plurality of combinations of the second guide pattern data and the second DSA pattern data,
simulation of the second guide pattern is carried out, then simulation of the second DSA pattern is carried out.

8. The method according to claim 1, wherein simulation of the second guide pattern and simulation of the second DSA pattern are lithography simulation carried out in the evaluation of the lithography method.

9. The method according to claim 1, wherein simulation of the second guide pattern and simulation of the second DSA pattern are carried out taking into consideration variation in dimensions caused by variation in manufacturing process conditions.

10. The method according to claim 1, wherein the second guide pattern simulation is carried out taking into consideration at least any of the form, material and dimensions of the second guide pattern.

11. The method according to claim 1, wherein the second DSA pattern simulation is carried out taking into consideration at least any of the DSA material (self assembly material), composition ratio, molecular weight, dimensions and process conditions.

12. The method according to claim 11, wherein the free energy of the second DSA pattern is obtained by carrying out simulation of the second DSA pattern.

13. The method according to claim 1, further comprising optically correcting one set or a plurality of sets of the second guide pattern data and the second DSA pattern data that are suitable for forming the pattern to be formed.

14. The method according to claim 1, wherein the optically correcting is at least one of an optical proximity correction and a resolution enhanced technology process.

15. The method according to claim 1, further comprising detecting defects in one set or a plurality of sets of the second guide pattern data and the second DSA pattern data that are suitable for forming the pattern to be formed.

16. The method according to claim 15, wherein the detecting defects is carried out by a lithography compliance checking (LCC) process.

17. A pattern data generation device, comprising: a pattern decomposition unit that decomposes data of a pattern to be formed into first guide pattern data and first DSA pattern data;
an evaluation pattern generation unit that generates a plurality of combinations of second guide pattern data and second DSA pattern data based on combinations of the first guide pattern data and the first DSA pattern data;
an evaluation unit that carries out simulation for each of the plurality of combinations of the second guide pattern data and the second DSA pattern data, and evaluates the simulation results using a predetermined evaluation function; and
an extraction unit that extracts one set or a plurality of sets of combinations that are suitable for forming the pattern to be formed, from among the plurality of combinations of the second guide pattern data and the second DSA pattern data, based on the evaluation results.

18. The device according to claim 17, wherein the evaluation function is at least one selected from the group consisting of a function related to the dimensional changes of the second DSA pattern with respect to the dimensional changes of the second guide pattern, a function related to the change in free energy of the second DSA pattern associated with process variations, a function related to the convergence behavior of the free energy of the second DSA pattern, and a function related to the dimensional changes of the second guide pattern and the second DSA pattern with respect to defect size.

19. A pattern data generation program executed on a computer, comprising:
decomposing data of a pattern to be formed into first guide pattern data and first DSA pattern data;
generating a plurality of combinations of second guide pattern data and second DSA pattern data based on combinations of the first guide pattern data and the first DSA pattern data;
evaluating by carrying out simulation for each of the plurality of combinations of the second guide pattern data and the second DSA pattern data, and evaluating the simulation results using a predetermined evaluation function; and
extracting one set or a plurality of sets of combinations that are suitable for forming the pattern to be formed, from among the plurality of combinations of the second guide pattern data and the second DSA pattern data, based on the evaluation results.

20. The program according to claim 19, wherein the evaluation function is at least one selected from the group consisting of a function related to the dimensional changes of the second DSA pattern with respect to the dimensional changes of the second guide pattern, a function related to the change in free energy of the second DSA pattern associated with process variations, a function related to the convergence behavior of the free energy of the second DSA pattern, and, a function related to the dimensional changes of the second guide pattern and the second DSA pattern with respect to defect size.
